(19) United States
(12) Patent Application Publication
(10) Pub. No.: US 2012/0319873 A1
(43) Pub. Date: Dec. 20, 2012

(54) ELECTRIC APPARATUS, INPUT APPARATUS AND METHOD THEREOF

(75) Inventor: AN-PING TAN, SHANGHAI CITY (CN)

(73) Assignees: MITAC RESEARCH (SHANGHAI) LTD., SHANGHAI (CN); MITAC INTERNATIONAL CORP., TAOYUAN COUNTY (TW)

(21) Appl. No.: 13/177,824

(22) Filed: Jul. 7, 2011

(30) Foreign Application Priority Data
Jun. 16, 2011 (CN) 201110162984.X

(51) Int. Cl. H03M 11/00

(52) U.S. Cl. 341/22

(57) ABSTRACT

The present invention discloses an electric apparatus, an input apparatus and a method thereof. The input apparatus comprises a plurality of keys, a storage unit and a processing unit. Wherein, the processing unit is electrically connected to the plurality of keys and the storage unit. Each key correspondingly generates a key signal based on the operation of each key by a user. The storage unit records a plurality of correspondences between a key group and a first key value represented by the key group which corresponds to at least two of the plurality of keys. The processing unit searches the plurality of correspondences based on the key signal, thereby correspondingly outputting the first key value which is represented by the key group.

### BACKGROUND OF THE INVENTION

1. Field of the Invention

The present invention relates to an electric apparatus, an input apparatus and a method thereof, and more particularly to an input apparatus applied in combined input keys and a method thereof.

2. Background of the Invention

The input method for regular keypads is performed by pressing a single key or inputting a key combination by pressing one key (Shift, Ctrl, Alt) in conjunction with another key. The key value that corresponds to each key has already been defined so it cannot be defined by the consumer themselves. Along with the rapid progress of technology, portable and handheld electronic products are becoming increasingly commonplace. The keypad area and number of keys on small-sized electronic products have been reduced compared to regular keypads. Moreover, physical keypads are gradually replaced by virtual keypads in order to achieve the goal of lowering the weight and reducing the size of electronic products to improve convenience of use. In particular, the key area and key size on virtual keyboards of either optical or screen-type displays can be adjusted depending on the design of the corresponding electronic products. While such keypad is more convenient to carry, it is inconvenient to use because the keys are too small (especially for elderly people and persons with poor vision) such that the users may input incorrectly and spend too much time to correct the mistakes.

In general, the inventor of this invention contemplated how to design an electric apparatus, input apparatus and a method to correct these current deficiencies and enhance its applicability to industry.

### SUMMARY OF THE INVENTION

In view of this problem of the above prior art, the purpose of this invention is to provide an electric apparatus, an input apparatus and a method to solve the input problem that is caused by the small size of regular keys and effectively enlarge the input range of keys to improve the convenience and accuracy of input.

According to the purpose of the present invention, the object of the present invention is to provide an input apparatus which includes a plurality of keys, a storage unit and a processing unit. Wherein, the plurality of keys are electrically connected to the processing unit, and each key correspondingly generates a key signal based on the operation of each key by a user. The storage unit is electrically connected to the processing unit and records a plurality of correspondences between a key group and a first key value which is represented by the key group. The key group corresponds to at least two of the plurality of keys. The processing unit searches the plurality of correspondences based on the key signal, thereby correspondingly outputting the first key value which is represented by the key group.

Preferably, once the processing unit receives a switching command, a second key value represented by each key is converted into the first key value represented by the key group.

Preferably, each correspondence in the storage unit further includes a third key value represented by the key group corresponding to each key, which has been pressed for a time interval. When the processing unit determines the time period during which the user presses the plurality of keys is greater than the time interval, the processing unit outputs the third key value.

Preferably, a plurality of correspondences are searched when entering a menu of dialing number.

According to the purpose of the present invention, another object of this invention is to provide an input method which is applied to an input apparatus. The input apparatus includes a plurality of keys, a storage unit and a processing unit. The input method includes the following steps: providing a plurality of keys; recording a plurality of correspondences between a key group and a first key value which is represented by the key group by a storage unit, wherein the key group corresponds to at least two of the plurality of keys; correspondingly generating a key signal based on the operation of each key by a user; searching the plurality of correspondences based on the key signal by a processing unit, thereby correspondingly outputting the first key value which is represented by the key group.

Preferably, the input method further includes the following steps: receiving a switching command by the processing unit; and converting a second key value represented by each key into the first key value represented by the key group by the processing unit after the processing unit receives the switching command.

Preferably, each correspondence further includes a third key value which is represented by the key group corresponding to each key, which has been pressed for a time interval. When the processing unit determines the time period during which the plurality of keys are pressed by the user is greater than the time interval, the processing unit outputs the third key value.

Preferably, a plurality of correspondences are searched when entering a menu of dialing number.

According to the purpose of the present invention, a further object of this invention is to provide an electric apparatus which includes a plurality of keys, a storage unit, a display unit and a processing unit. Wherein, the processing unit is electrically connected to a plurality of keys, a storage unit and a display unit. The plurality of keys correspondingly generates a key signal based on the operation of each key by a user. The storage unit records a plurality of correspondences between a key group and a first key value which is represented by the key group. Wherein, the key group corresponds to at least two of the plurality of keys. The processing unit searches the plurality of correspondences based on the key signal, thereby correspondingly outputting the first key value which is represented by the key group and controlling the display unit to display the first key value.

Preferably, the processing unit receives a switching command and converts a second key value which is represented by each key into the first key value which is represented by the key group.

Preferably, each correspondence in the storage unit further includes a third key value which is represented by the key group corresponding to each key which has been pressed for a time interval. When the processing unit determines the time period during which the user presses the plurality of keys is greater than the time interval, the processing unit outputs the third key value and controls the display unit to display the third key value.

Preferably, the electric apparatus includes a tablet computer, a desktop computer, a notebook computer or a personal digital assistant (PDA).

As stated above, the electric apparatus, the input apparatus and the method thereof of the present invention possess one or more of the following advantages:

(1) The electric apparatus, the input apparatus and the method thereof can improve input speed and accuracy by setting the same key value for a number of keys.

(2) The electric apparatus, the input apparatus and the method thereof can switch the key value represented by the key based on the time period during which the key in the key group is pressed and thereby increase variety of key values represented by the key and achieve greater input convenience.

### BRIEF DESCRIPTION OF THE DRAWING

FIG. 1 is a block diagram of the input apparatus according to the present invention.

FIG. 2 is a block diagram of the electric apparatus according to the present invention.

FIG. 3 is a diagram of the first embodiment of the electric apparatus according to the present invention.

FIG. 4 is a diagram of the second embodiment of the electric apparatus according to the present invention.

FIG. 5 is a flow chart of the input method according to the present invention.

FIG. 6 is another flow chart of the input method according to the present invention.

### DETAILED DESCRIPTION OF THE PREFERRED EMBODIMENTS

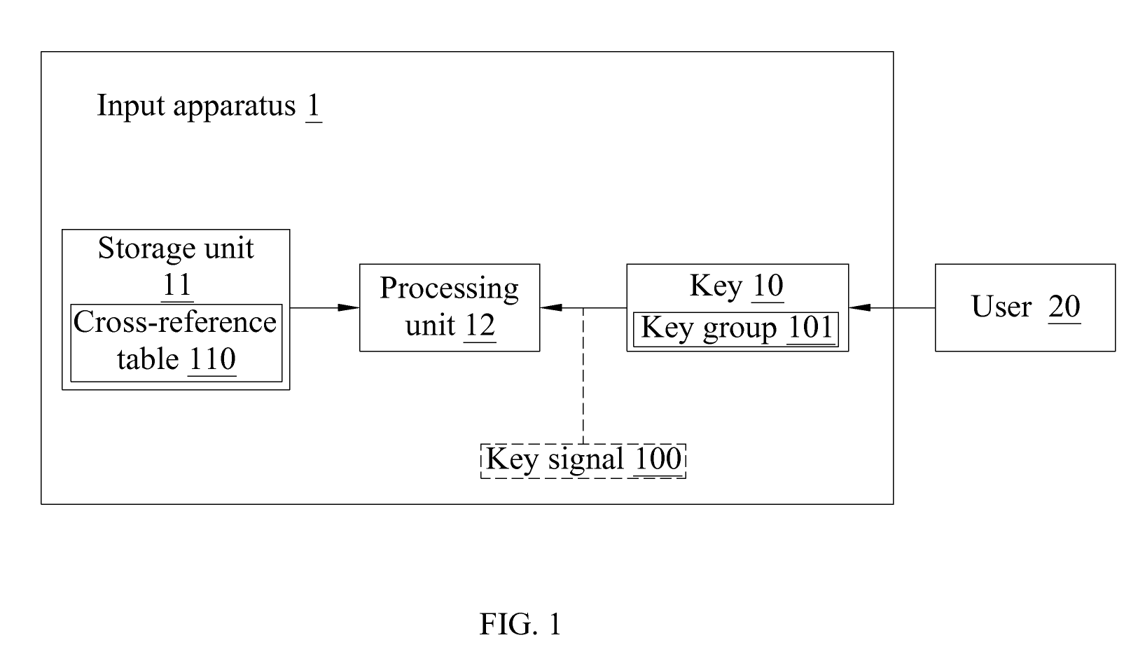

With reference to FIG. 1, it is a block diagram of the input apparatus according to the present invention. As shown in FIG. 1, an input apparatus 1 includes a plurality of keys 10, a storage unit 11 and a processing unit 12. Wherein the processing unit 12 is electrically connected to a plurality of keys 10 and storage unit 11. The storage unit 11 stores a cross-reference table 110, which records a plurality of correspondences between a key group 101 and a first key value 120 represented by the key group 101. Wherein, the key group 101 corresponds to at least two of the plurality of keys 10. That is the key group 101 can correspond to two or more keys 10 and one key group 101 corresponds to one first key value 120. Therefore, the plurality of keys 10 can correspond to the same first key value 120 so as to expand the key area of the same key value. After the user 20 presses the key 10, the pressed key 10 correspondingly generates a key signal 100. When the processing unit 12 receives the key signal 100, the processing unit 12 searches the plurality of correspondences recorded in the cross-reference table 110 based on the key signal 100 to obtain the first key value 120 represented by the key group 101 belonging to the pressed key 10 and thereby outputs the first key value 120.

Wherein, the plurality of keys 10 can be virtual keys or physical keys or assembled into a QWERTY keypad.

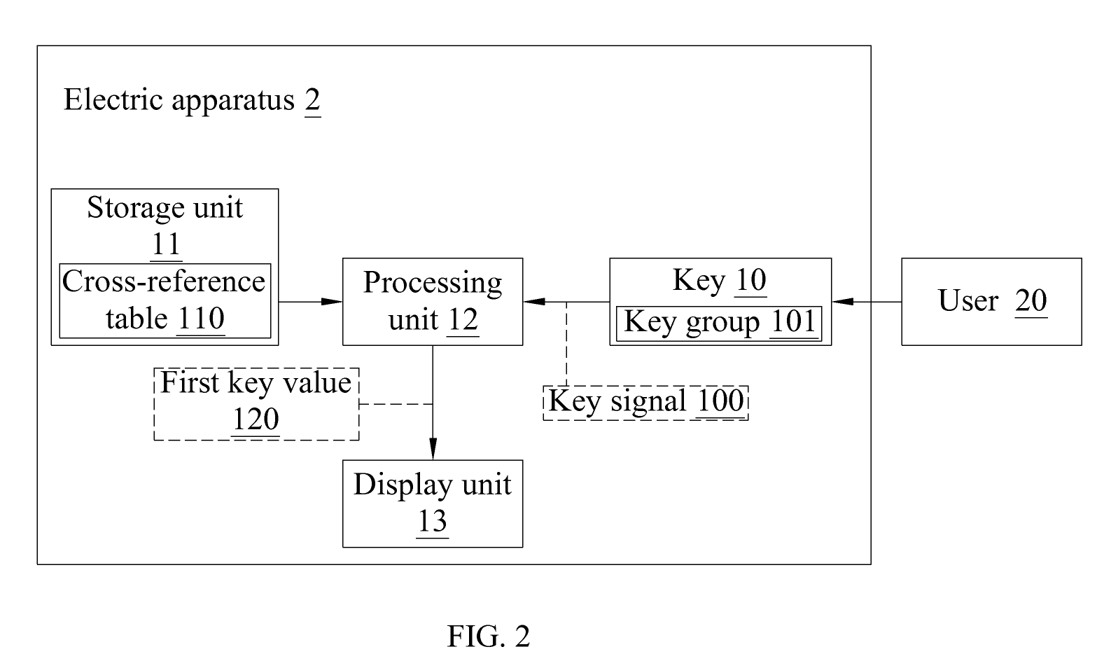

With reference to FIG. 2, it is a block diagram of the electric apparatus according to the present invention. As shown in FIG. 2, the layout is generally similar to FIG. 1. In comparison, the difference between the two is the electric apparatus 2 which further includes a display unit 13. After the processing unit 12 receives the key signal 100, the processing unit 12 searches the plurality of correspondences recorded in a cross-reference table 110 based on the key signal 100 to obtain the first key value 120 represented by the key group 101 belonging to the pressed key 10. Moreover, the processing unit 12 controls the display unit 13 to display the first key value 120. When entering a menu of dialing number, a plurality of correspondences are searched.

Wherein, the electric apparatus 2 includes a tablet computer, desktop computer, notebook computers, mobile phone or a personal digital assistant (PDA).

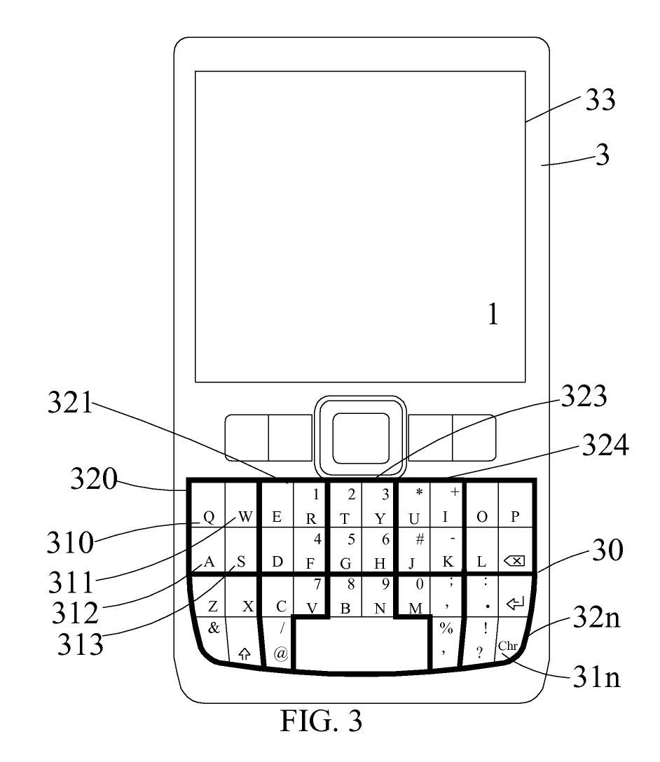

With reference to FIG. 3, there is a diagram showing the first embodiment of the electric apparatus according to the present invention. In the figure, the electric apparatus is executed by a mobile phone 3; the display unit is executed by a display screen 33. The mobile phone 3 has a QWERTY keypad 30, which comprises a plurality of keys 310, 311, 312, 313 . . . 31n. When the electric apparatus is initialized by a user, the plurality of keys 310, 311, 312, 313 . . . 31n can be divided into a plurality of key group 320, 321, 323, 324 . . . 32n. As shown in FIG. 3, keys 310, 311, 312 and 313 can be divided into the key group 320 by the user and a first key value, which is represented by the key group 320, can be defined as 1. The rest of the keys can be deduced by analogy so that the first key value represented by the plurality of key groups 320, 321, 323, 324 . . . , 32n are defined in order as 1, 2, 3, 4 . . . , 0. Moreover, a storage unit is used to record a plurality of correspondences between each key group and its first key value.

When the user presses one of the keys 310, 311, 312 or 313, the pressed key generates a key signal. The processing unit searches the correspondence recorded in the storage unit based on the key signal and thereby obtains the first key value, which is represented by the key group 320. The processing unit then controls the display screen 33 to display the first key value that is the Arabic numeral 1 on display screen 33. By the enlargement of the range of keys with the same key value, the electric apparatus can make it more convenient for the user to input Arabic numerals and thereby improve the speed and accuracy of input. Therefore, the electric apparatus resolves the problem of each key value being provided by a single key on general keypads. That is, the electric apparatus eliminates the inconvenience to users with poor vision or elderly users from having to go back to correct mistakes, which are made because the wrong keys is pressed as a result of the keys being too small, and re-input.

In FIG. 3, in standard keypad use mode, a second key value Q is represented by the key 310; a second key value W is represented by the key 311; a second key value A is represented by the key 312; and a second key value S is represented by the key 313. The user can select one or any combination of the plurality of keys 310, 311, 312, 313 . . . , 31n to generate a switching command, which can switch between the standard keypad use mode and custom keypad use mode. For example, in the standard keypad use mode, the user can press keys simultaneously like pressing the second key value Ctrl and T. The pressed key then generates a switching command and the standard keypad use mode is switched to the custom keypad use mode. Subsequently, in the custom key use mode, the user can easily press the desired first key value based on the division of the key group 320.

Wherein, blocks of each key group 320, 321, 323, 324 . . . , 32n can be display by a backlit method. For example, backlight colors or flickering display can be used to distinguish each key group 320, 321, 323, 324 . . . , 32n.

In addition, in the custom keypad use mode, each correspondence stored in the storage unit further includes a third key value represented by the key group corresponding to each key, which is pressed for a preset time interval, For example, in the custom keypad use mode, when the user presses one of the keys 310, 311, 312 or 313, the display screen 33 displays the second key value, which is the Arabic numeral 1. Meanwhile, if the user continues to press and hold any of the keys 310, 311, 312 and 313 for a time period longer than the time interval (i.e. 3 seconds) preset in the processing unit, the third key value is then output (such as: calculation symbols +, −, * or /). In this way, numerous third key values can be generated by pressing the key for different time intervals which can solve the problem of making input errors when using small and medium sized keys with conventional technology and achieve the object of convenient input.

In this embodiment, Arabic numerals are used as the second key value to overcome the problem of frequent input errors that most people have when they are entering phone numbers but the second value does not have to be limited to numbers for this invention. The second value can be English letter, phonetic symbols, special symbols or Arabic numeral key values.

In addition, though the time interval for the above embodiment is 3 seconds as an example to describe the invention concept, the invention is not limited to the time interval and it may be set to any time desired by the user.

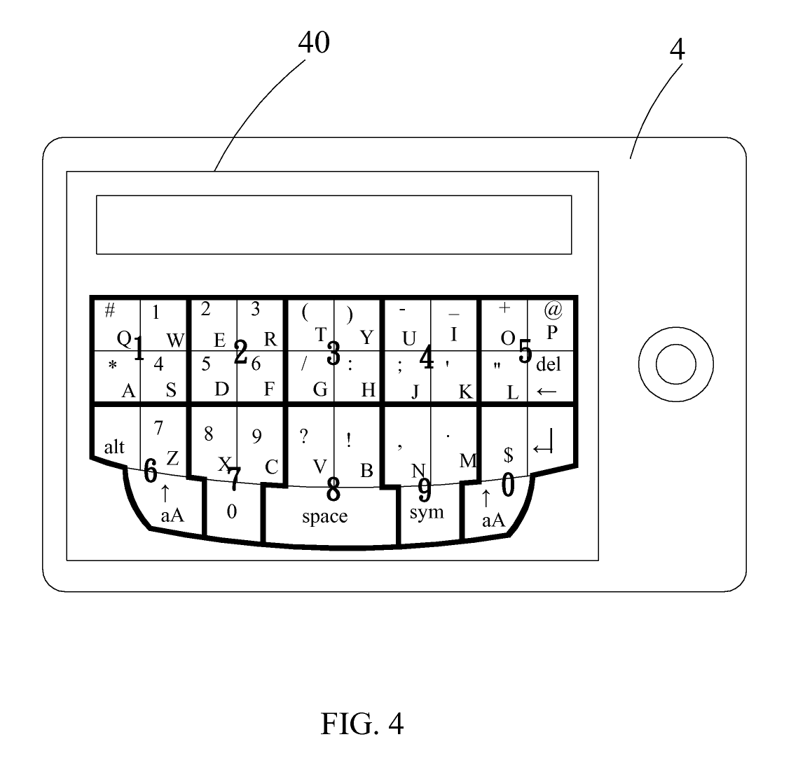

With reference to FIG. 4, there is a diagram showing the second embodiment of the electric apparatus according to the present invention. As shown in the figure, the layout is generally similar to FIG. 3. In comparison, the difference between the two is the electric apparatus, which is executed by a personal digital assistant 4(PDA) comprising a touch panel 40 executed by combining a virtual keypad including a plurality of keys with a display unit. In this embodiment, the number of keys displayed on the touch panel 40 is different from the number of keys in the first embodiment. A user can divide the keys into different key groups. As shown in FIG. 4, the plurality of keys are divided into 10 key groups by a user, in which each key group individually represents its own individual first key value. In this way, the area of the keys with the same key value is enlarged which not only overcomes the problem of a single key representing a single key value in the prior art which forces the user to accurately press on the key in order to input the key value correctly but also achieves the object of easily and faster key value input.

Wherein, different colors can be used to display individual blocks of each key group; or the touch panel 40 can be used to display the key value represented by each key group for differentiation but there is not limitation to said display method for this invention. The display method may be set as desired by the user.

Although the concept of the input method has been described in the above description relating to the electric apparatus, the flow chart of the input method according to the present invention is shown here to provide a detailed description.

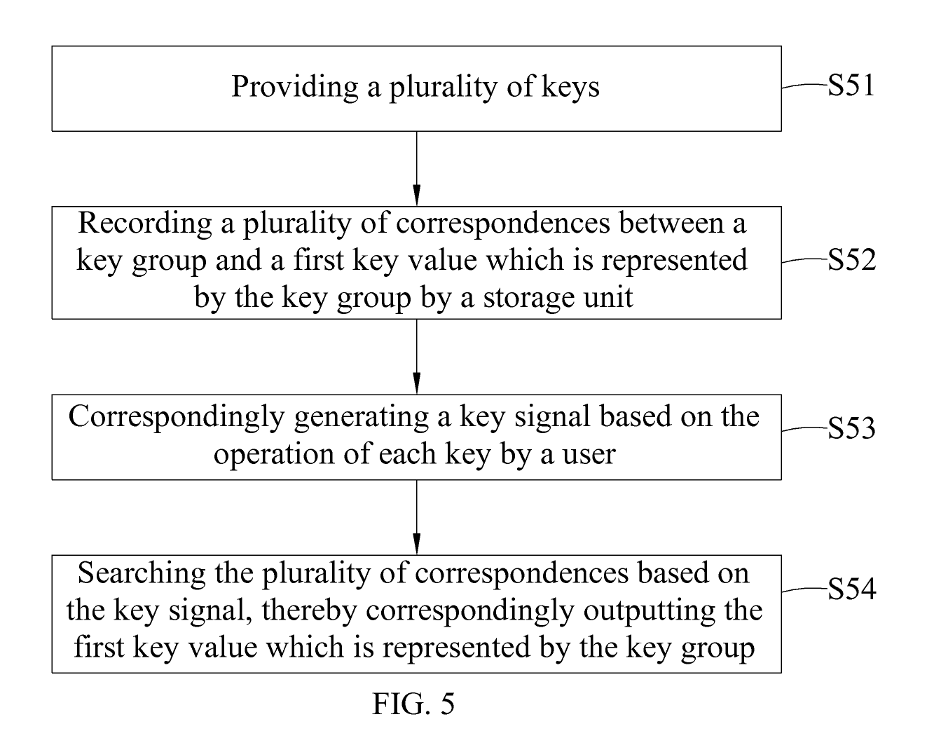

With reference to FIG. 5, there is a flow chart of the input method according to the present invention, wherein the input method is applied to an input apparatus. The input apparatus includes a plurality of keys, a storage unit and a processing unit. As shown in the figure, the input method comprises the following steps:

S51: providing a plurality of keys;

S52: recording a plurality of correspondences between a key group and a first key value which is represented by the key group by a storage unit, wherein the key group corresponds to at least two of the plurality of keys;

S53: correspondingly generating a key signal based on the operation of each key by a user; and

S54: searching the plurality of correspondences based on the key signal by a processing unit, thereby outputting the first key value represented by the corresponding key group

Wherein, each correspondence further includes a third key value represented by the key group corresponding to each key, which is pressed for a time interval. When the processing unit determines the time period during which the user presses the plurality of keys is greater than the time interval, the processing unit outputs the third key value.

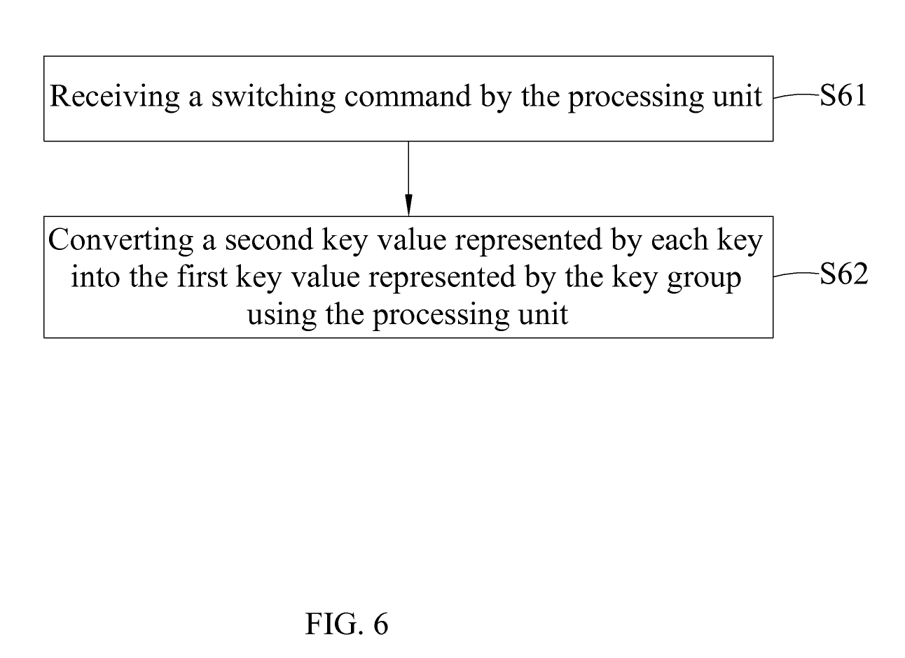

With reference to FIG. 6, there is another flow chart of the input method according to the present invention. As shown in the figure, the input method for this invention further comprises the following steps:

S61: receiving a switching command by the processing unit; and

S62: converting a second key value represented by each key into the first key value represented by the key group using the processing unit.

The detailed description of the component function and operation for the above steps is the same as the content of the electric apparatus and the input apparatus according to the present invention, so it will not be repeated here.

In summation of the description above, by setting the same key value for a plurality of keys, this invention's electric apparatus, input apparatus, and a method thereof expands the area of the key with the same key value and further switches the key value represented by the key based on the time period that the key is pressed and held so that a key group represents many different key values. As the key group takes the place of a single key corresponding to a key value, the present invention overcomes the problem of the prior art where users have to accurately press a single key in order to input a key value, eliminates the time wasted by frequent input errors, and improves input speed and accuracy.

The above description is illustrative only and is not to be considered limiting. Various modifications or changes can be made without departing from the spirit and scope of the invention. All such equivalent modifications and changes shall be included within the scope of the appended claims.

What is claimed is:

1. An input apparatus, comprising:
a plurality of keys, wherein each key correspondingly generates a key signal based on the operation of each key by a user;
a storage unit recording a plurality of correspondences between a key group and a first key value which is represented by the key group, wherein the key group corresponds to at least two of the plurality of keys; and
a processing unit electrically connected to the plurality of keys and the storage unit, and searching the correspondences based on the key signal, thereby outputting the first key value represented by the corresponding key group.

2. The input apparatus of claim 1, wherein after the processing unit receives a switching command, a second key value which is represented by the key is converted into the first key value which is represented by the key group.

3. The input apparatus of claim 1, wherein each correspondence further includes a third key value which is represented by the key group corresponding to the key, which is pressed and held for a time interval, and when the processing unit determines the time period during which the plurality of keys are pressed by the user is greater than the time interval, the processing unit outputs the third key value.

4. The input apparatus of claim 1, wherein a plurality of correspondences are searched when entering a menu of dialing number.

5. An input method, including the following steps:
providing a plurality of keys;
recording a plurality of correspondences between a key group and a first key value which is represented by the key group by a storage unit, wherein the key group corresponds to at least two of the plurality of keys;
correspondingly generating a key signal based on the operation of each key by a user; and
searching the plurality of correspondences based on the key signal by a processing unit, thereby outputting the first key value represented by the corresponding key group.

6. The input method of claim 5, further including the following steps:
receiving a switching command by the processing unit; and
converting a second key value represented by the key into the first key value represented by the key group using the processing unit.

7. The input method of claim 5, wherein each correspondence further includes a third key value which is represented by the key group corresponding to the key, which is pressed and held for a time interval, and when the processing unit determines the time period during which the plurality of keys are pressed by the user is greater than the time interval, the processing unit outputs the third key value.

8. The input method of claim 5, wherein a plurality of correspondences are searched when entering a menu of dialing number.

9. An electric apparatus, including:
a plurality of keys, wherein each key correspondingly generates a key signal according to the operation of each key by a user;
a storage unit recording a plurality of correspondences between a key group and a first key value which is represented by the key group, wherein the key group corresponds to at least two of the plurality of keys;
a display unit displaying the first value; and
a processing unit electrically connected to the plurality of keys, the storage unit and the display unit, and searching the plurality of correspondences based on the key signal, thereby correspondingly outputting the first key value which is represented by the key group and controlling the display unit to display the first key value.

10. The electric apparatus of claim 9, wherein the processing unit receives a switching command and then converts a second key value represented by the key into the first key value represented by the key group.

11. The electric apparatus of claim 9, wherein each correspondence in the storage unit further includes a third key value which is represented by the key group corresponding to the key, which is pressed and held for a time interval, and when the processing unit determines the time period during which the plurality of keys are pressed by the user is greater than the time interval, the processing unit outputs the third key value and controls the display unit to display the third key value.

12. The electric apparatus of claim 9, wherein the electric apparatus includes a tablet computer, desktop computer, notebook computer, mobile phone or a personal digital assistant (PDA).
